(19) United States
(12) Patent Application Publication
(10) Pub. No.: US 2022/0302493 A1
(43) Pub. Date: Sep. 22, 2022

(54) POUCH-TYPE ALL-SOLID-STATE BATTERY HAVING REFERENCE ELECTRODE AND METHOD OF MANUFACTURING SAME

(71) Applicants: Hyundai Motor Company, Seoul (KR); Kia Corporation, Seoul (KR)

(72) Inventors: Yong Guk Gwon, Busan (KR); Hoon Seok, Suwon-Si (KR); Min Sun Kim, Goyang-Si (KR); Yong Seok Choi, Seoul (KR); Ju Min Kim, Daejeon (KR)

(73) Assignees: Hyundai Motor Company, Seoul (KR); Kia Corporation, Seoul (KR)

(21) Appl. No.: 17/683,574

(22) Filed: Mar. 1, 2022

(30) Foreign Application Priority Data
Mar. 18, 2021 (KR) 10-2021-0035114

(51) Int. Cl. H01M 10/058; H01M 50/105

(52) U.S. Cl. CPC H01M 10/058; H01M 50/105

(57) ABSTRACT

A pouch-type all-solid-state battery having a reference electrode and a method of manufacturing the same, includes: a unit cell including an anode portion, a cathode portion, and a solid electrolyte portion having a sheet shape and located between the anode portion and the cathode portion; and an external member including a space for accommodating the unit cell therein, wherein the solid electrolyte portion includes: an electrode accommodating portion in which the anode portion and the cathode portion are accommodated; and an extension portion having a predetermined area extending from a side surface of the electrode accommodating portion, wherein a reference electrode portion is positioned on one surface of the extension portion.

### CROSS REFERENCE TO RELATED APPLICATION

The present application claims priority to Korean Patent Application No. 10-2021-0035114, filed Mar. 18, 2021, the entire contents of which is incorporated herein for all purposes by this reference.

### BACKGROUND OF THE INVENTION

### Field of the Invention

The present invention relates to a pouch-type all-solid-state battery having a reference electrode, and to a method of manufacturing the same.

### Description of Related Art

A typical cell is a two-electrode cell including a cathode and an anode. The two-electrode cell is characterized in that based on a reference electrode, that is, a counter electrode functioning as an anode, the characteristics of a working electrode functioning as a cathode are measured and evaluated. That is, what may be measured in the two-electrode cell is just voltage and resistance of the entire cell, but specific characteristics of each of the cathode and anode cannot be measured.

A three-electrode cell is a cell including a cathode, an anode, and a reference electrode. In the three-electrode cell, voltage, resistance, and so on of each of the cathode and the anode may be measured by comparing the reference electrode with the cathode and with the anode. That is, voltage, resistance, and so on of each of the cathode and the anode thereof can be analyzed by separating voltage, resistance, and so on of the entire cell. Therefore, it is easy to identify the detailed characteristics of each component inside the cell.

To manufacture an all-solid-state battery having a high capacity and a high energy density, it is necessary to analyze a potential curve and a detailed resistance of a battery. An all-solid-state battery having a three-electrode cell is a useful means for analyzing a potential curve, a detailed resistance, a reaction, and so on of each of the cathode and the anode.

Currently, a three-electrode cell exists only in a pouch cell using a liquid electrolyte or a pressed cell using a solid electrolyte, and a three-electrode cell that exists in a pouch cell-type all-solid-state battery has not been provided.

The information included in this Background of the Invention section is only for enhancement of understanding of the general background of the invention and may not be taken as an acknowledgement or any form of suggestion that this information forms the prior art already known to a person skilled in the art.

### BRIEF SUMMARY

Various aspects of the present invention are directed to providing a pouch cell-type all-solid-state battery having a reference electrode.

Various aspects of the present invention are to realize a condition that a pouch-type all-solid-state battery may be properly performed.

Various aspects of the present invention are to provide a method of manufacturing a reference electrode that satisfies the above-mentioned condition.

The objectives of the present invention are not limited to the foregoing. The objectives of the present invention will be able to be clearly understood through the following description and to be realized by the means described in the claims and combinations thereof.

According to various exemplary embodiments of the present invention, there is provided a pouch-type all-solid-state battery, the battery including: a unit cell including an anode portion, a cathode portion, and a solid electrolyte portion having a sheet shape and interposed between the anode portion and the cathode portion; and an external member in which a space capable of accommodating the unit cell is provided, wherein the solid electrolyte portion includes: an electrode accommodating portion in which the anode portion and the cathode portion are accommodated; and an extension portion having a predetermined area extending from a side surface of the electrode accommodating portion, and wherein a reference electrode portion is positioned on one surface of the extension portion.

An area of the anode portion may be equal to or greater than an area of the cathode portion.

An area of the electrode accommodating portion may be equal to or greater than an area of the anode portion.

The reference electrode portion may be positioned on a surface of the solid electrolyte portion where the surface is a same surface on which the cathode portion is positioned.

A minimum distance between the cathode portion and the reference electrode portion may be 0.1 cm to 3 cm.

The reference electrode portion may be spaced from an edge portion of the extension portion by at least 0.1 cm.

The solid electrolyte portion may have a lithium-ion conductivity of 1×10⁻³ S/cm to 5×10⁻² S/cm.

A distance (B) between the anode portion and the reference electrode portion and a lithium-ion conductivity (a) of the solid electrolyte portion may satisfy the following Relational Expression 1:

3,000≥B/a [cm²/S]≥2 [Relational Expression 1]

According to various exemplary embodiments of the present invention, there is provided a method of manufacturing a pouch-type all-solid-state battery, the method including: mounting a unit cell in which an anode portion, a solid electrolyte portion having a sheet shape, and a cathode portion are sequentially stacked inside an external member, wherein the solid electrolyte portion includes: an electrode accommodating portion in which the anode portion and the cathode portion are accommodated; and an extension portion having a predetermined area extending from a side surface of the electrode accommodating portion, primarily pressurizing the unit cell; mounting a reference electrode portion on the extension portion; secondarily pressurizing a resultant of the mounting a reference electrode portion; and sealing the external member.

An area of the anode portion may be equal to or greater than an area of the cathode portion.

An area of the electrode accommodating portion may be equal to or greater than an area of the anode portion.

The primarily pressurizing may be isotropic pressurizing with a pressure equal to or greater than 300 MPa.

According to various exemplary embodiments of the present invention, checking potential curves of the anode portion and the cathode portion during charging and discharging thereof is possible, so that it is possible to analyze characteristics of each electrode.

According to various exemplary embodiments of the present invention, using a method for analyzing the anode portion and the cathode portion, the method such as a direct current-internal resistance (DC-IR) measurement, an electrochemical impedance spectroscopy (EIS), and so on can be realized, so that it is possible to analyze a detailed resistance in a real cell condition.

According to various exemplary embodiments of the present invention, without secondary processing before and after charging and discharging, such as disassembling and analyzing the all-solid-state battery or manufacturing and analyzing a half-cell, the characteristics of the all-solid-state battery may be simply and precisely analyzed at a specific point in time, such as a state of charge (SOC).

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a view exemplarily illustrating a pouch-type all-solid-state battery according to various exemplary embodiments of the present invention;

FIG. 2 is a bottom view exemplarily illustrating a unit cell of the pouch-type all-solid-state battery according to various exemplary embodiments of the present invention;

FIG. 3 is a top view exemplarily illustrating the unit cell of the pouch-type all-solid-state battery according to various exemplary embodiments of the present invention;

FIG. 4 is a view exemplarily illustrating another exemplary embodiment of the pouch-type all-solid-state battery according to various exemplary embodiments of the present invention;

FIG. 5 is a first reference view to explain a method of manufacturing an all-solid-state battery according to various exemplary embodiments of the present invention;

FIG. 6 is a second reference view to explain the method of manufacturing an all-solid-state battery according to various exemplary embodiments of the present invention;

FIG. 7 is a third reference view to explain the method of manufacturing an all-solid-state battery according to various exemplary embodiments of the present invention;

FIG. 8A is a graph showing a result of measuring potentials of an anode portion, a cathode portion, and an entire cell of a pouch-type all-solid-state battery according to Example 1;

FIG. 8B is a graph showing a result of measuring potentials of an anode portion, a cathode portion, and an entire cell of a pouch-type all-solid-state battery according to Comparative Example 1;

FIG. 8C is a graph showing a result of measuring potentials of an anode portion, a cathode portion, and an entire cell of a pouch-type all-solid-state battery according to Comparative Example 2;

FIG. 9A is an image showing a result of analyzing an interface between a solid electrolyte portion and a reference electrode portion of a pouch-type all-solid-state battery according to Example 2 by use of a scanning electron microscope (SEM); and

FIG. 9B is an image showing a result of analyzing an interface between a solid electrolyte portion and a reference electrode portion of a pouch-type all-solid-state battery according to Comparative Example 3 by use of a scanning electron microscope (SEM).

It may be understood that the appended drawings are not necessarily to scale, presenting a somewhat simplified representation of various features illustrative of the basic principles of the present invention. The specific design features of the present invention as included herein, including, for example, specific dimensions, orientations, locations, and shapes will be determined in part by the particularly intended application and use environment.

In the figures, reference numbers refer to the same or equivalent parts of the present invention throughout the several figures of the drawing.

### DETAILED DESCRIPTION

Reference will now be made in detail to various embodiments of the present invention(s), examples of which are illustrated in the accompanying drawings and described below. While the present invention(s) will be described in conjunction with exemplary embodiments of the present invention, it will be understood that the present description is not intended to limit the present invention(s) to those exemplary embodiments. On the other hand, the present invention(s) is/are intended to cover not only the exemplary embodiments of the present invention, but also various alternatives, modifications, equivalents and other embodiments, which may be included within the spirit and scope of the present invention as defined by the appended claims.

In the appended drawings, like numerals are used to represent like elements. In the drawings, the dimensions of the elements are enlarged for easier understanding of the present invention. Although the terms first, second, etc. may be used to describe various elements, these elements may not be limited by the terms. The terms are used only to distinguish one element from another. For example, a first element may be termed a second element, and similarly, a second element may be termed a first element without departing from the scope of the present invention. A singular expression includes a plural expression unless the context clearly indicates otherwise.

In various exemplary embodiments of the present invention, terms such as “include”, “contain”, “have”, etc. may be understood as designating that features, numbers, steps, operations, elements, parts or combinations thereof exist and not as precluding the existence of or the possibility of adding one or more other features, numbers, steps, operations, elements, parts or combinations thereof in advance. Furthermore, when an element such as a layer, a film, a region, a substrate, etc. is referred to as being “on” another element, it can be “directly on” the another element or an intervening element may further be present. Likewise, when an element such as a layer, a film, a region, a substrate, etc. is referred to as being “under” another element, it can be “directly under” the another element or an intervening element may further be present.

Unless specified otherwise, all the numbers, values and/or expressions representing the amount of components, reaction conditions, polymer compositions or mixtures are approximations reflecting various uncertainties of measurement occurring in obtaining those values and may be understood to be modified by “about”. Also, unless specified otherwise, all the numerical ranges included in various exemplary embodiments of the present invention are continuous and include all the values from the minimum values to the maximum values included in the ranges. Furthermore, when the ranges indicate integers, all the integers from the minimum values to the maximum values included in the ranges are included unless specified otherwise.

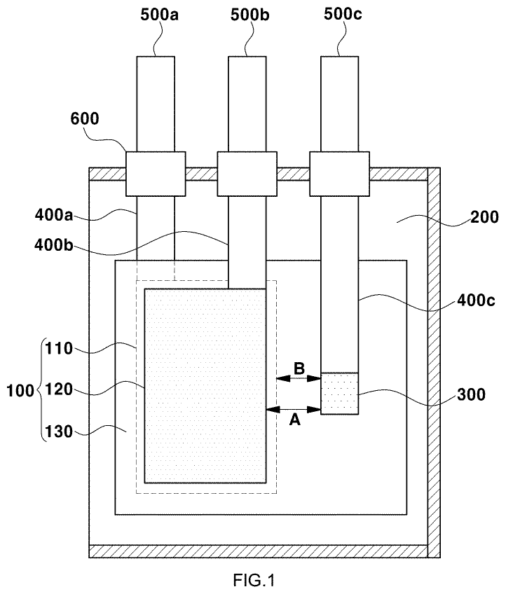

FIG. 1 is a view exemplarily illustrating a pouch-type all-solid-state battery according to various exemplary embodiments of the present invention. Referring to FIG. 1, the pouch-type all-solid-state battery includes a unit cell 100 and an external material 200 in which a space configured for accommodating the unit cell 100 is provided.

The unit cell 100 includes an anode portion 110, a cathode portion 120, and a solid electrolyte portion 130 having a sheet shape and interposed between the anode portion 110 and the cathode portion 120.

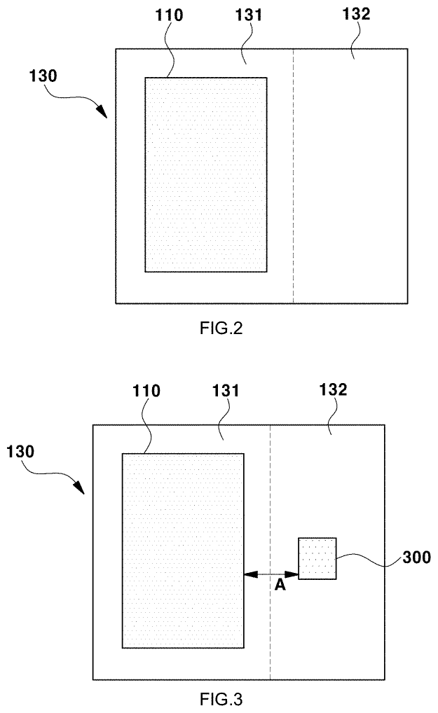

FIG. 2 is a bottom view exemplarily illustrating the unit cell 100. FIG. 3 is a top view exemplarily illustrating the unit cell 100.

The solid electrolyte portion 130 may include an electrode accommodating portion 131 in which the anode portion 110 and the cathode portion 120 are accommodated and an extension portion 132 having a predetermined area extending from a side surface of the electrode accommodating portion 131.

The anode portion 110 may be positioned on one surface of the electrode accommodating portion 131, and the cathode portion 120 may be positioned on the other surface of the electrode accommodating portion 131.

An area of the anode portion 110 is equal to or greater than an area of the cathode portion 120. Furthermore, an area of the electrode accommodating portion 131 is equal to or greater than an area of the anode portion 110.

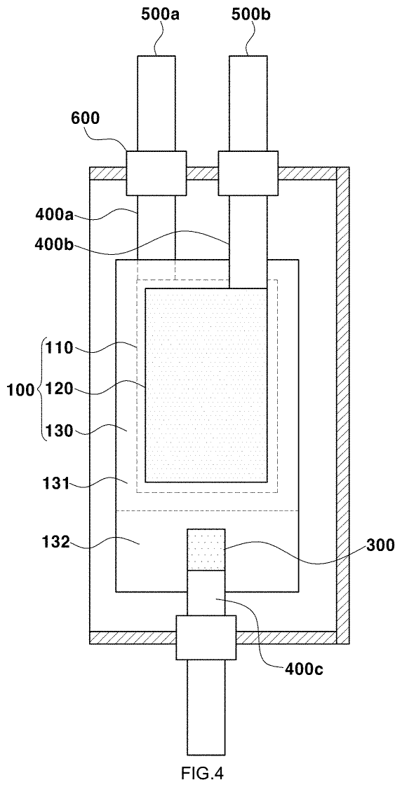

As illustrated in FIG. 1, FIG. 2, and FIG. 3, the extension portion 132 may extend along in a width direction of the external material 200 from a side surface of the electrode accommodating portion 131. Furthermore, as illustrated in FIG. 4, the extension portion 132 may extend along in a longitudinal direction of the external material 200 from a side surface of the electrode accommodating portion 131.

A reference electrode portion 300 may be positioned on one surface of the extension portion 132. The reference electrode portion 300 may be positioned on a surface of the extension portion 132 where the surface is the same surface on which the cathode portion 120 is positioned.

The reference electrode portion 300 may be spaced from the cathode portion 120 by 0.1 cm to 3 cm. Alternatively, a minimum distance (A) between the cathode portion 120 and the reference electrode portion 300 may be 0.1 cm to 3 cm. Based on the top view as illustrated in FIG. 3, the minimum distance (A) between any point at an edge portion of the cathode portion 120 and any point at an edge portion of the reference electrode portion 300 may be 0.1 cm to 3 cm. The reference electrode portion 300 needs to be spaced apart at least 0.1 cm from the cathode portion 120, which is to prevent the reference electrode portion 300 from being in contact with the cathode portion 120 even if the reference electrode portion 300 is spread by being pressed. On the other hand, if the reference electrode portion 300 is spaced apart more than 3 cm from the cathode portion 120, resistance may increase and signals from each of the electrode portions 110 and 120 may not be measured properly, and the size of the all-solid-state battery may be increased unnecessarily.

The reference electrode portion 300 may be spaced from the edge portion of the extension portion 132 by at least 0.1 cm. If a distance between the reference electrode portion 300 and the edge portion of the extension portion 132 is less than 0.1 cm, there is a risk in that the reference electrode portion 300 may be in contact with the external material 200 when the reference electrode portion 300 is spread by being pressed.

The all-solid-state battery may further include an anode tab 400a, a cathode tab 400b, and a reference electrode tab 400c. The anode tab 400a is electrically connected to the anode portion 110 and accommodated in the external material 200, the cathode tab 400b is electrically connected to the cathode portion 120 and accommodated in the external material 200, and the reference electrode tab 400c is electrically connected to the reference electrode portion 300 and accommodated in the external material 200.

The all-solid-state battery may further include an anode lead 500a, a cathode lead 500b, and a reference electrode lead 500c. The anode lead 500a is electrically connected to the anode tab 400a and extended externally by passing through the external member 200, the cathode lead 500b is electrically connected to the cathode tab 400b and extended externally by passing through the external member 200, and the reference electrode lead 500c is electrically connected to the reference electrode tab 400c and extended externally by passing through the external member 200.

Sealing portions 600 may be disposed at portions at which the anode lead 500a, the cathode lead 500b, and the reference electrode lead 500c are passing through the external member 200, respectively, so that the external member 200 may maintain a sealed state.

In various exemplary embodiments of the present invention, the reference electrode portion 300 is applied in the pouch-type all-solid-state battery, and the present invention is directed to propose specific conditions in which the reference electrode portion 300 performs properly. For reference, one of the conditions is the distance between the reference electrode portion 300 and the cathode portion 120.

In the all-solid-state battery, a distance (B) between the anode portion 110 and the reference electrode portion 300 and a lithium-ion conductivity (a) may satisfy the following Relational Expression 1. Assuming that the anode portion 110 and the reference electrode portion 300 are positioned on the same plane, the distance B between the anode portion 110 and the reference electrode portion 300 is defined as a minimum distance from one end portion of the anode portion 110 positioned at the reference electrode portion 300 to one end portion of the reference electrode portion 300 positioned at the anode portion 110 side thereof.

3,000≥B/a [cm²/S]≥2 [Relational Expression 1]

A lithium-ion conductivity of the solid electrolyte portion 130 may be 1×10⁻³ S/cm to 5×10⁻² S/cm.

The Relational Expression 1 indicates a limit distance that the reference electrode portion 300 may be efficiently functioned according to the lithium-ion conductivity (a) of the solid electrolyte portion 130.

A ratio (B/a) of the distance (B) between the anode portion 110 and the reference electrode portion 300 to the lithium-ion conductivity (a) may be 2 to 3,000, or 50 to 1,500, as shown in the Relational Expression 1. When the value of the Relational Expression 1 indicates the lower limit which is less than 2, which means the distance (B) between the anode portion 110 and the reference electrode portion 300 is close, there may be a risk of being short-circuited due to a contact of the reference electrode portion 300 with the cathode portion 120. On the other hand, when the value of the Relational Expression 1 indicates the upper limit which is more than 3,000, a noise may occur in a potential of the anode portion 110 and the cathode portion 120, the potential measured through the reference electrode portion 300.

A method of manufacturing an all-solid-state battery according to various exemplary embodiments of the present invention may include: mounting a unit cell in which an anode portion, a solid electrolyte portion having a sheet shape, and a cathode portion are sequentially stacked inside an external member; primarily pressurizing the unit cell; mounting a reference electrode portion on an extension portion; secondarily pressurizing a resultant of the mounting a reference electrode portion; and sealing the external member.

First, as illustrated in FIG. 5, the unit cell 100, which is described above, may be mounted at the internal surface of the external member 200. At the instant time, when the unit cell 100 is mounted, the anode tab 400a, the cathode tab 400b, the anode lead 500a, and the cathode lead 500b may be provided together to be suitable for each electrode. Furthermore, the sealing portions 600 may be disposed at positions at which the anode lead 500a and the cathode lead 500b are being in contact with the external member 200, respectively.

Next, the unit cell 100 may be primarily pressurized. Through the primarily pressurizing, interfaces between the anode portion 110, the cathode portion 120, and the solid electrolyte portion 130 may be uniformly formed.

The primarily pressurizing may be isotropic pressurizing performed at least 300 MPa. When the pressure of the primarily pressurizing is less than 300 MPa, there may be difficult to form the interfaces between each configuration of the unit cell 100.

After the primarily pressurizing, a thickness of the solid electrolyte portion 130 may be 30 μm to 150 μm.

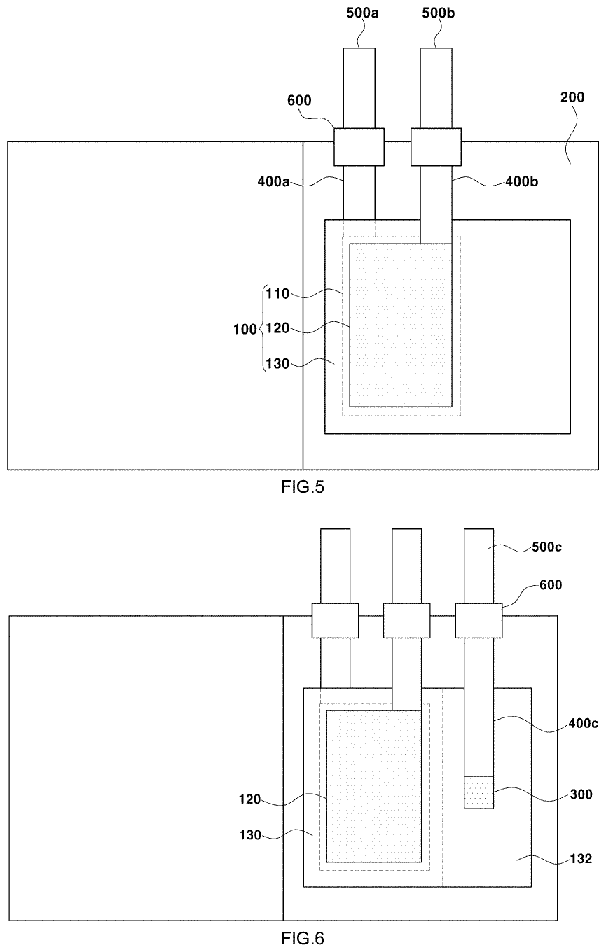

Accordingly, as illustrated in FIG. 6, the reference electrode portion 300 may be spaced apart with a predetermined distance from the cathode portion 120 and may be mounted on the extension portion 132 of the solid electrolyte portion 130. At the instant time, the reference electrode tab 400c, the reference electrode lead 500c, and the sealing portions 600 may be placed together.

After mounting the reference electrode portion 300, a resultant of the mounting a reference electrode portion may be secondarily pressurized. The secondarily pressurizing is performed to uniformly form an interface between the solid electrolyte portion 130 and the reference electrode portion 300.

The secondarily pressurizing may be isotropic pressurizing performed at 10 MPa to 20 MPa. When a pressure of the secondarily pressurizing is less than 10 MPa, there may be difficulty forming the interface between the solid electrolyte portion 130 and the reference electrode portion 300, and when the pressure of the secondarily pressurizing is higher than 20 MPa, an internal short-circuit may occur due to the reference electrode portion 300 penetrating into the solid electrolyte portion 130.

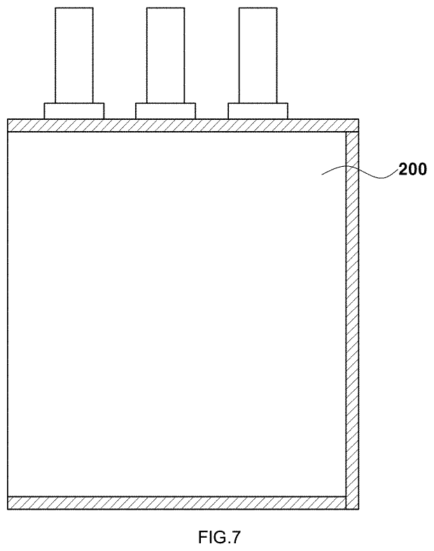

Finally, as illustrated in FIG. 7, the pouch-type all-solid-state battery may be obtained by sealing the external member 200.

Hereinafter, the present invention will be described more specifically through examples. However, these examples are provided only for the understanding of the present invention, and the scope of the present invention is not limited to these examples in any sense.

### Example 1

To verify the condition of the aforementioned Relational Expression 1, a pouch-type all-solid-state battery the same as illustrated in FIG. 1 was manufactured. Lithium metal was used as a reference electrode portion. The lithium-ion conductivity (a) of a solid electrolyte portion was 2×10⁻³ S/cm. The distance (B) between an anode portion and a reference electrode portion was adjusted to 1 cm.

In the pouch-type all-solid-state battery according to the Example 1, the ratio (B/a) of the distance (B) between the anode portion and the reference electrode portion to the lithium-ion conductivity (a) was 500.

### Comparative Example 1

The same procedure as in the Example 1 was performed to manufacture a pouch-type all-solid-state battery, except that the distance (B) between the anode portion and the reference electrode portion was adjusted to 10 cm.

In the pouch-type all-solid-state battery according to the Comparative Example 1, the ratio (B/a) of the distance (B) between the anode portion and the reference electrode portion to the lithium-ion conductivity (a) was 5,000.

### Comparative Example 2

The same procedure as in the Example 1 was performed to manufacture a pouch-type all-solid-state battery, except that the distance (B) between the anode portion and the reference electrode portion was adjusted to 0.002 cm.

In the pouch-type all-solid-state battery according to the Comparative Example 2, the ratio (B/a) of the distance (B) between the anode portion and the reference electrode portion to the lithium-ion conductivity (a) was 1.

### Experimental Example 1

Potentials of each cathode portion, each anode portion, and each of the entire cells of pouch-type all-solid-state batteries according to the Example 1, the Comparative Example 1, and the Comparative Example 2 were measured.

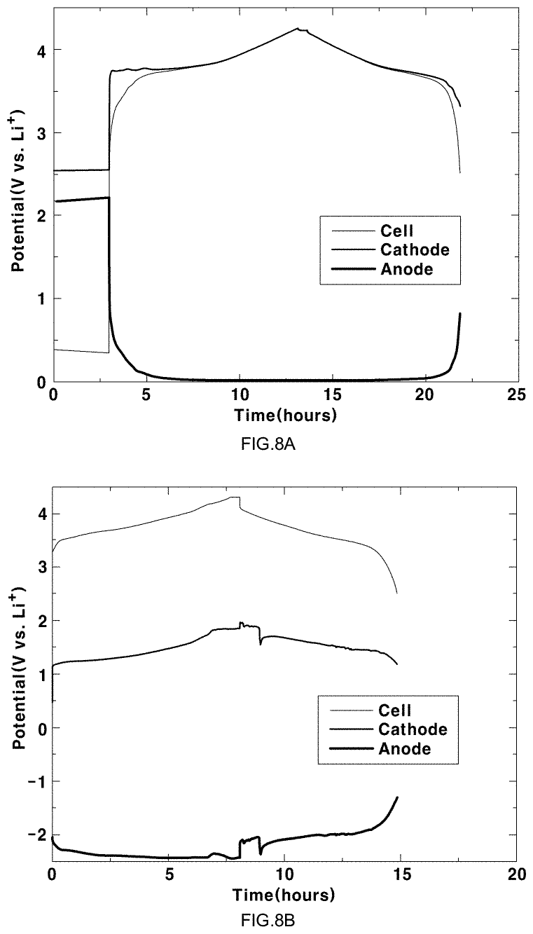

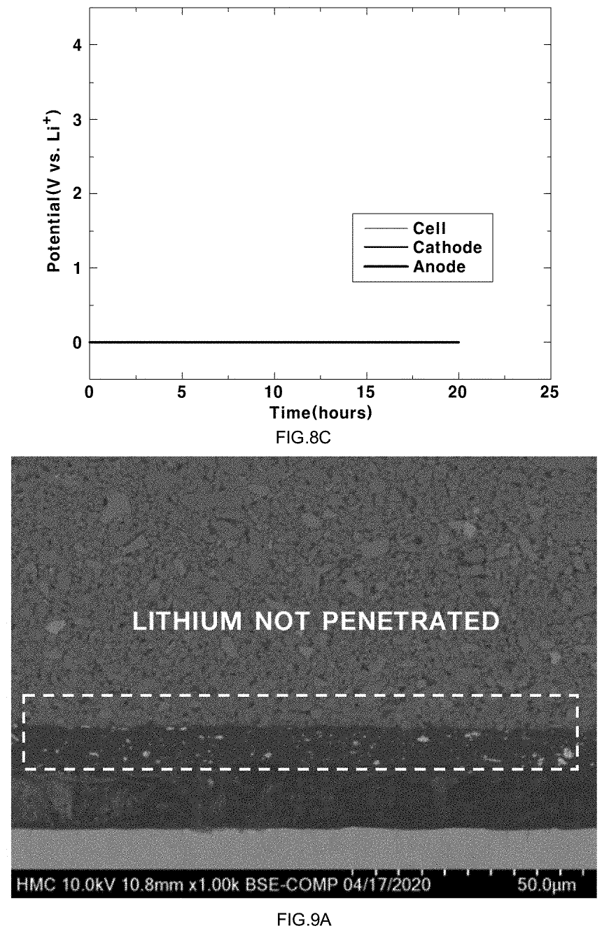

FIG. 8A, FIG. 8B and FIG. 8C are graphs showing measured results of potentials of pouch-type all-solid-state batteries according to the Example 1, the Comparative Example 1, and the Comparative Example 2, respectively. As illustrated in FIG. 8A, in the Example 1, it may be seen that the potentials of the cathode portion and the anode portion were separated and measured without a noise. However, as illustrated in FIG. 8B, in the Comparative Example 1, it may be seen that the potentials of the cathode portion and the anode portion have a noise entirely, and as illustrated in FIG. 8C, in the Comparative Example 2, it may be seen that the potentials of the cathode portion and the anode portion were not separated so that the analysis could not be performed.

### Example 2

To verify the pressurizing condition at the secondarily pressurizing according to the method of manufacturing a pouch-type all-solid-state battery according to various exemplary embodiments of the present invention, a pouch-type all-solid-state battery the same as illustrated in FIG. 1 was manufactured. Lithium metal was used as a reference electrode portion, and the pressure of the secondarily pressurizing was adjusted to 10 MPa.

### Comparative Example 3

The same procedure as in the Example 2 was performed to manufacture a pouch-type all-solid-state battery, except that the pressure of the secondarily pressurizing was adjusted to 50 MPa.

### Experimental Example 2

Scanning electron microscope analysis was performed on an interface between the solid electrolyte portion and the reference electrode portion according to each of the pouch-type all-solid-state batteries according to the Example 2 and the Comparative Example 3.

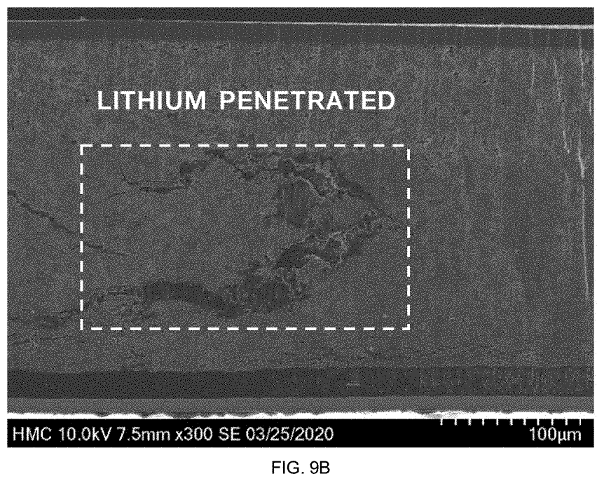

FIG. 9A and FIG. 9B are images showing results of scanning electron microscope analysis of potentials of the pouch-type all-solid-state batteries according to the Example 2 and the Comparative Example 3, respectively. As illustrated in FIG. 9A, in the Example 2, it may be seen that lithium metal which is the reference electrode portion did not penetrate into the solid electrolyte portion. However, as illustrated in FIG. 9B, in the Comparative Example 3, it may be seen that lithium metal is penetrated into the reference electrode portion, which is due to the excessive pressure of the secondarily pressurizing.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present invention have been presented for purposes of illustration and description. They are not intended to be exhaustive or to limit the present invention to the precise forms disclosed, and obviously many modifications and variations are possible in light of the above teachings. The exemplary embodiments were chosen and described to explain certain principles of the present invention and their practical application, to enable others skilled in the art to make and utilize various exemplary embodiments of the present invention, as well as various alternatives and modifications thereof. It is intended that the scope of the present invention be defined by the Claims appended hereto and their equivalents.

What is claimed is:

1. A pouch-type all-solid-state battery, the battery comprising:
a unit cell including an anode portion, a cathode portion, and a solid electrolyte portion having a sheet shape and located between the anode portion and the cathode portion; and
an external member including a space for accommodating the unit cell therein,
wherein the solid electrolyte portion includes:
an electrode accommodating portion in which the anode portion and the cathode portion are accommodated; and
an extension portion having a predetermined area extending from a side surface of the electrode accommodating portion, wherein a reference electrode portion is positioned on one surface of the extension portion.

2. The battery of claim 1, wherein an area of the anode portion is equal to or greater than an area of the cathode portion.

3. The battery of claim 1, wherein an area of the electrode accommodating portion is equal to or greater than an area of the anode portion.

4. The battery of claim 1, wherein the reference electrode portion is positioned on a surface of the solid electrolyte portion where the surface is a same surface on which the cathode portion is positioned.

5. The battery of claim 1, wherein a minimum distance between the cathode portion and the reference electrode portion is 0.1 cm to 3 cm.

6. The battery of claim 1, wherein the reference electrode portion is spaced from an edge portion of the extension portion by at least 0.1 cm.

7. The battery of claim 1, wherein the solid electrolyte portion has a lithium-ion conductivity of 1×10⁻³ S/cm to 5×10⁻² S/cm.

8. The battery of claim 1, wherein a distance (B) between the anode portion and the reference electrode portion and a lithium-ion conductivity (a) of the solid electrolyte portion satisfy the following Relational Expression 1:
3,000≥B/a [cm²/S]≥2 [Relational Expression 1]

9. A method of manufacturing a pouch-type all-solid-state battery, the method comprising:
mounting a unit cell in which an anode portion, a solid electrolyte portion having a sheet shape, and a cathode portion are sequentially stacked inside an external member,
wherein the solid electrolyte portion includes:
an electrode accommodating portion in which the anode portion and the cathode portion are accommodated; and
an extension portion having a predetermined area extending from a side surface of the electrode accommodating portion,
primarily pressurizing the unit cell;
mounting a reference electrode portion on the extension portion;
secondarily pressurizing a resultant of the mounting a reference electrode portion; and
sealing the external member.

10. The method of claim 9, wherein an area of the anode portion is equal to or greater than an area of the cathode portion.

11. The method of claim 9, wherein an area of the electrode accommodating portion is equal to or greater than an area of the anode portion.

12. The method of claim 9, wherein the primarily pressurizing is isotropic pressurizing with a pressure equal to or greater than 300 MPa.

13. The method of claim 9, wherein after the primarily pressurizing, a thickness of the solid electrolyte portion is 30 μm to 150 μm.

14. The method of claim 9, wherein the reference electrode portion is positioned on a surface of the solid electrolyte portion where the surface is a same surface on which the cathode portion is positioned.

15. The method of claim 9, wherein the secondarily pressurizing is isotropic pressurizing the resultant at a pressure of 10 MPa to 20 MPa.

16. The method of claim 9, wherein a minimum distance between the cathode portion and the reference electrode portion is 0.1 cm to 3 cm.

17. The method of claim 9, wherein the reference electrode portion is spaced from an edge portion of the extension portion by at least 0.1 cm.

18. The method of claim 9, wherein the solid electrolyte portion has a lithium-ion conductivity of 1×10⁻³ S/cm to 5×10⁻² S/cm.

19. The method of claim 9, wherein a distance (B) between the anode portion and the reference electrode portion and a lithium-ion conductivity (a) of the solid electrolyte portion satisfy the following Relational Expression 1:
3,000≥B/a [cm²/S]≥2 [Relational Expression 1]
